(19) United States
(12) Patent Application Publication
(10) Pub. No.: US 2003/0058060 A1
(43) Pub. Date: Mar. 27, 2003

(54) Noise reduction high frequency circuit

(75) Inventor: Etsushi Yamamoto, Tokyo-to (JP)

Correspondence Address: Keating & Bennett LLP, Suite 312, 10400 Eaton Place, Fairfax, VA, 22030, US

(73) Assignee: Murata Manufacturing Co., Ltd., Nagaokakyo-shi (JP)

(21) Appl. No.: 10/245,290

(22) Filed: Sep. 18, 2002

(30) Foreign Application Priority Data
Sep. 21, 2001 (JP) 2001-289376
Aug. 7, 2002 (JP) 2002-230205

(51) Int. Cl. H03H 7/38

(52) U.S. Cl. 333/32

(57) ABSTRACT

A noise-reduction high-frequency circuit includes a transmission line, a noise filter provided at the stage prior to the transmission line, and an impedance matching circuit for matching the characteristic impedance of the transmission line. The impedance matching circuit includes a termination circuit that includes a resistance and a power supply and is located at the stage subsequent to the transmission line.

### BACKGROUND OF THE INVENTION

1. Field of the Invention

The present invention generally relates to high-frequency circuits, and more particularly, to a high-frequency circuit that can reduce noise in a certain frequency range.

2. Description of the Related Art

In high-frequency circuits, particularly in digital circuits that operate at high speeds, in order to eliminate EMI (electromagnetic interference) and other undesirable conditions, a band elimination noise filter for reducing noise in a certain frequency range may be inserted into a previous stage adjacent to a transmission line (e.g., see Japanese Patent Unexamined Application Publication No. 9-69745).

When, however, such a noise filter is inserted, a stop band specified in the specification of the noise filter, i.e., a frequency at which the impedance of the noise filter is maximized, may not necessarily be equal to a frequency band at which the noise reduction effect is actually maximized.

For example, a noise filter having an impedance characteristic shown in FIG. 10A (the peaks of impedances R and Z are about 550 MHz in the specification) was inserted into the stage prior to a transmission line, as shown in FIG. 16, and an experiment was performed. The experiment showed that the noise reduction effect was maximized at a frequency of about 200 MHz, which was significantly shifted from the stop band specified in the specification of the noise filter. In FIGS. 10A and 10B, hatched portions with lines extending in a single direction indicate frequency bands in which noise is reduced by 10 dB or more, and hatched portions with lines that cross each other indicate frequency bands in which the noise reduction effect is maximized.

The result of thorough examination thereof revealed that, depending on a position in the transmission line, a current level and a voltage level were different, i.e., a standing wave was generated. The examination also revealed that the deviation in frequency is particularly prominent when a current and/or voltage standing wave was generated.

Consequently, the present applicant discovered that the deviation in the frequency band, i.e., a deviation between a stop band specified in the specification of a noise filter and a band in which the noise reduction effect is actually exhibited, is caused by the generation of the current and/or voltage standing wave, and thus contemplated and developed the present invention.

A cause of the generation of a standing wave in a high-frequency range is attributed to an impedance mismatching, i.e., a discrepancy between the characteristic impedance of a transmission line and the impedance of a load connected to the receiving end thereof. In other words, a reflection wave that is generated at an end of the transmission line in the case of the mismatching causes the generation of the standing wave. In general, when a device, such as an IC, that provides a load is used, since the impedance of such a device is significantly high compared to the characteristic impedance of the transmission line, no impedance matching is often provided for the transmission line. Use of a conventional configuration in which a termination circuit is provided at the stage subsequent to a transmission line (i.e., Japanese Patent Unexamined Application Publication No. 6-61836) is only intended to improve a transmission waveform. Such an arrangement, thus, can suppress transmission waveform distortion (see FIG. 9A), but has a disadvantage in that radiated electromagnetic noise is increased due to an increase in an electric current flowing in the transmission line. A configuration in which a termination circuit and a noise filter are both used has not been conventionally available.

### SUMMARY OF THE INVENTION

In order to overcome the problems described above, preferred embodiments of the present invention provide devices that ensure that the noise elimination effect to be realized in a stop band specified in the specification of a noise filter is achieved regardless of a transmission line characteristic.

According to a first preferred embodiment of the present invention, a noise-reduction high-frequency circuit includes a transmission line, a noise filter provided at the stage prior to the transmission line, and an impedance matching circuit for matching the characteristic impedance of the transmission line. The impedance matching is provided at the stage subsequent to the transmission line.

According to the first preferred embodiment of the present invention, since the impedance matching circuit accomplishes impedance matching of the transmission line, no current and/or voltage standing wave is generated in the transmission line. In general, the generation of a current and/or voltage standing wave impairs the noise elimination effect of a noise filter in a frequency range in which the standing wave is generated. Thus, the first preferred embodiment of the present invention can offer a flat characteristic, i.e., a characteristic in which the electric-current level and the voltage level do not change, through the use of the impedance matching circuit. As a result, this arrangement can achieve a noise elimination effect in a stop band specified in the specification of the noise filter, regardless of a transmission line characteristic. This also means that this arrangement can improve the efficiency of the noise filter and can enhance the design versatility of the transmission line. In addition, this arrangement can suppress transmission waveform distortion using the effect of the impedance matching circuit.

The impedance matching circuit may be connected to ground or a constant voltage supply.

The arrangement in which the impedance matching circuit is connected to ground can provide the same advantages as the first preferred embodiment of the invention, with a significantly simple configuration. In addition, the arrangement in which the matching circuit is connected to the constant voltage allows electric current to be drawn from a power supply in accordance with the High/Low level of digital signals. Additionally, an arrangement in which the impedance matching circuits are connected to the corresponding ground and the constant voltage supply can set an electric current supplied to the subsequent stage to any value, by the combination of the impedances of the impedance matching circuits, and can also reduce an electric current drawn from the previous stage.

The impedance matching circuit may include a resistance element and a capacitor which are connected in series. In this case, the resistance element has an impedance that is substantially equal to the characteristic impedance of the transmission line and the capacitor has a capacitance that sufficiently suppresses waveform distortion.

This arrangement can reduce power consumption compared to a case in which the impedance matching circuit has only a resistance element.

The impedance matching circuit may include a semiconductor element. Preferably, the semiconductor element is a diode. Either arrangement can provide an intended advantage with a simple configuration. In particular, the case in which a diode is used can reduce the power consumption compared to a case in which a resistance element is used.

According to a second preferred embodiment of the present invention, a noise-reduction high-frequency circuit includes a transmission line, and a noise filter provided adjacent to the transmitting end of the transmission line and spaced away from the transmitting end toward the receiving end of the transmission line. The high frequency circuit further includes an impedance matching circuit, located at a stage subsequent to the transmission line, for matching the characteristic impedance of the transmission line.

According to a third preferred embodiment of the present invention, a noise-reduction high-frequency circuit includes a transmission line, a noise filter provided at a stage prior to the transmission line, and an impedance matching circuit for matching the characteristic impedance of the transmission line. The impedance matching circuit is provided adjacent to the receiving end of the transmission line and is spaced away from the receiving end toward the transmitting end of the transmission line.

According to a fourth preferred embodiment of the present invention, a noise-reduction high-frequency circuit includes a transmission line, and a noise filter provided adjacent to the transmitting end of the transmission line and spaced away from the transmitting end toward the receiving end of the transmission line. The high-frequency circuit further includes an impedance matching circuit for matching the characteristic impedance of the transmission line. The impedance matching circuit is provided adjacent to the receiving end of the transmission line and is spaced away from the receiving end toward the transmitting end of the transmission line.

According to the second to fourth preferred embodiments of the present invention, the impedance matching circuit also accomplishes impedance matching with the transmission line between the transmitting end and the impedance matching circuit. Thus, such an arrangement can suppress current and/or voltage standing waves generated in the transmission line, and can achieve a noise elimination effect in a stop band specified in the specification of the noise filter, regardless of the characteristics of the transmission line. In addition, the second to fourth preferred embodiments can each suppress transmission waveform distortion, using the effect of the impedance matching circuit.

Other features, elements, characteristics and advantages of the present invention will become more apparent from the following detailed description of preferred embodiments thereof with reference to the attached drawings.

### BRIEF DESCRIPTION OF THE DRAWINGS

FIG. 1 is a schematic block diagram showing the configuration of high-frequency circuit according to a first preferred embodiment of the present invention;

FIG. 2 is a schematic block diagram showing the configuration of a high-frequency circuit according to a second preferred embodiment of the present invention;

FIG. 3 is a schematic block diagram showing the configuration of a high-frequency circuit according to a third preferred embodiment of the present invention;

FIG. 4 is a schematic block diagram showing the configuration of a high-frequency circuit according to a fourth preferred embodiment of the present invention;

FIG. 5 is a schematic block diagram showing the configuration of a high-frequency circuit according to a fifth preferred embodiment of the present invention;

FIG. 6 is a schematic block diagram showing the configuration of a high-frequency circuit according to a sixth preferred embodiment of the present invention;

FIG. 7 is a schematic block diagram showing the configuration of a high-frequency circuit according to a seventh preferred embodiment of the present invention;

FIGS. 8A, 8B, and 8C each are a graph showing the spectrum of electromagnetic noise generated from a transmission line similar to one of the first preferred embodiment of the present invention, FIG. 8A showing a case in which nothing is attached to the transmission line, FIG. 8B showing a case in which only a noise filter is attached, and FIG. 8C showing the first preferred embodiment of the present invention in which the noise filter and a termination circuit are attached;

FIGS. 9A, 9B, and 9C each provides a graph showing a transmission waveform resulting from a transmission line similar to the one of the first preferred embodiment of the present invention, FIG. 9A showing a case in which nothing is attached to the transmission line, FIG. 9B showing a case in which only a noise filter is attached, and FIG. 9C showing the first preferred embodiment in which the noise filter and a termination circuit are attached;

FIGS. 10A and 10B each provides a graph showing the frequency characteristic of a noise filter and a frequency band in which the noise reduction effect is actually maximized and demonstrating the effect of the first preferred embodiment of the present invention, FIG. 10A showing a case in which only a noise filter is attached and FIG. 10B showing the first preferred embodiment in which the noise filter and a termination circuit are attached;

FIGS. 11A and 11B each provides a graph showing the frequency characteristic of a noise filter and a frequency band in which the noise reduction effect is actually maximized and demonstrating the effect of a first variation of the first preferred embodiment, FIG. 11A showing a case in which only a noise filter is attached and FIG. 11B showing a first variation in which the noise filter and a termination circuit are attached;

FIGS. 12A and 12B each are a graph showing the frequency characteristic of a noise filter and a frequency band in which the noise reduction effect is actually maximized and demonstrating the effect of a second variation of the first preferred embodiment, FIG. 12A showing a case in which only a noise filter is attached and FIG. 12B showing a second variation in which the noise filter and a termination circuit are attached;

FIG. 13 is a schematic block diagram showing the configuration of a high-frequency circuit according to an eighth preferred embodiment of the present invention;

FIG. 14 is a schematic block diagram showing the configuration of a high-frequency circuit according to a ninth preferred embodiment of the present invention;

FIG. 15 is a schematic block diagram showing the configuration of a high-frequency circuit according to a tenth preferred embodiment of the present invention; and

FIG. 16 is a block diagram showing a high-frequency circuit of the related art.

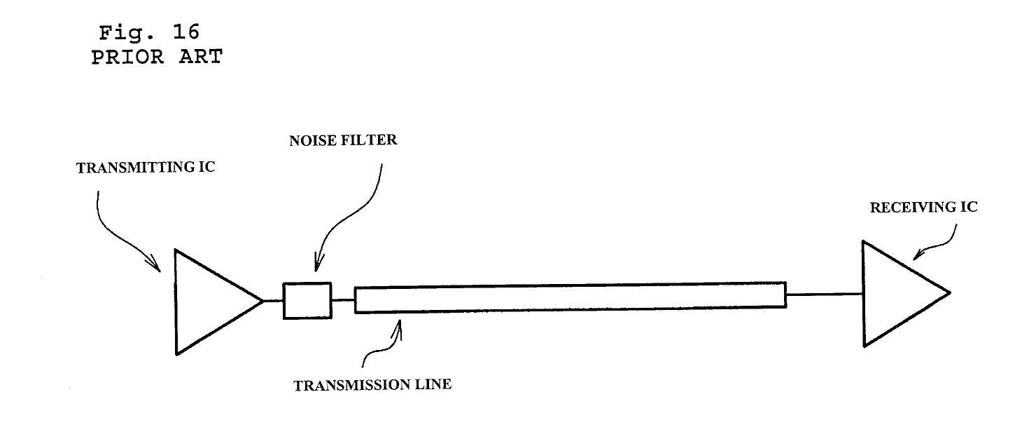

### DETAILED DESCRIPTION OF PREFERRED EMBODIMENTS

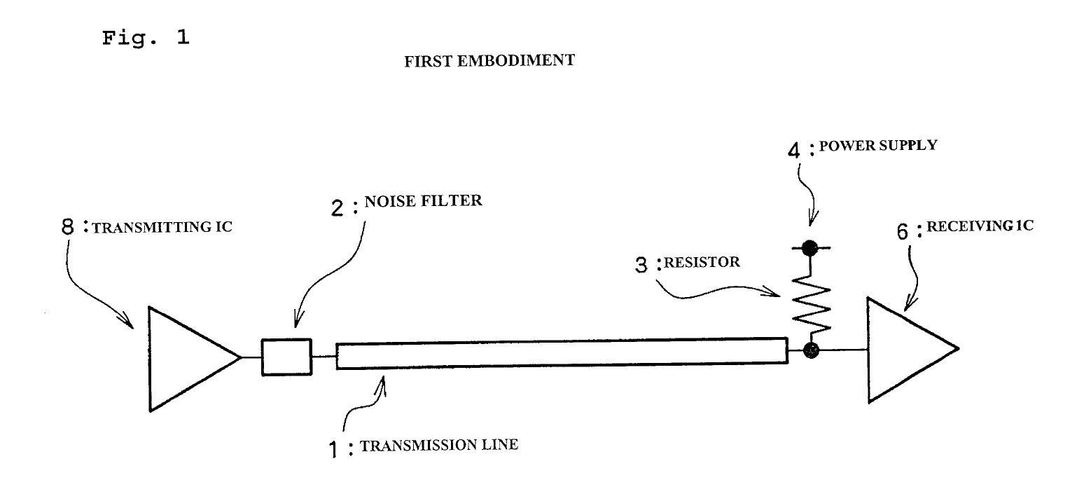

Preferred embodiments of the present invention will now be described with reference to the accompanying drawings. Referring to FIG. 1, a high-frequency circuit according to a first preferred embodiment uses so-called “active parallel termination” to provide a termination circuit. A noise filter 2 is connected to the stage prior to a transmission line 1, and a resistor 3 and a power supply 4 are connected to the stage subsequent to the transmission line 1. Further, a transmitting IC 8 is connected to the stage prior to the noise filter 2, and a receiving IC 6 is connected to the stage subsequent to the resistor 3.

The resistor 3 and the power supply 4 constitute a termination circuit. The resistance of the resistor 3 preferably has substantially the same value as the characteristic impedance of the transmission line 1, thereby accomplishing impedance matching with the transmission line 1. The power supply 4 is a constant voltage supply.

The noise filter 2 is a band elimination filter for reducing signals in a certain frequency range, and preferably uses, for example, an element having an inductance component. The rejection frequency (center frequency) of the stop band specified in the specification of the noise filter 2 is preferably 550 MHz.

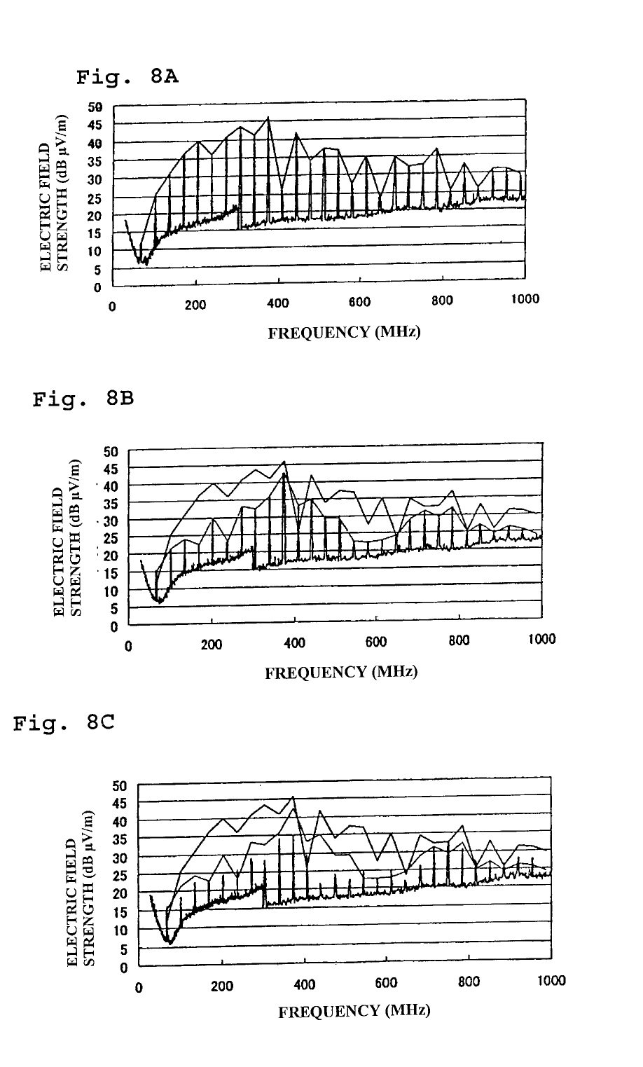

The operation of the high-frequency circuit of the first preferred embodiment configured as described above will now be described. FIGS. 8A, 8B, and 8C each show the spectrum of electromagnetic noise generated from the transmission line 1 that is similar to the one of the first preferred embodiment. Specifically, FIG. 8A shows a case in which nothing is attached to the transmission line 1, and FIG. 8B shows a case in which only the noise filter 2 is attached to the transmission line 1. As is apparent from the comparison of both cases, when only the noise filter 2 is attached, the frequency at which the noise reduction effect is maximized is about 200 MHz, which is significantly shifted from 550 MHz, which is the rejection frequency specified in the specification of the noise filter 2.

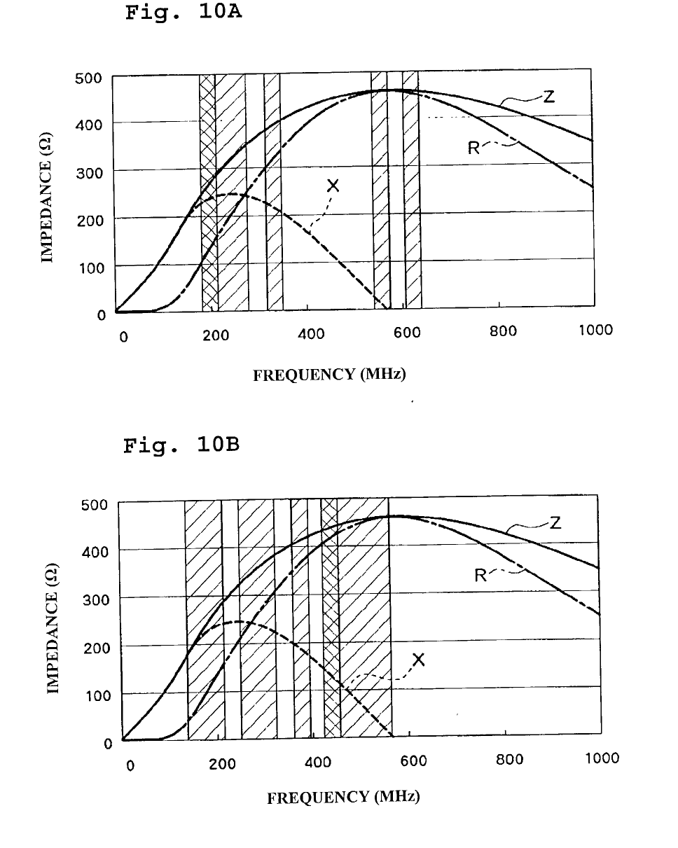

In contrast, FIG. 8C shows a case according to the first preferred embodiment in which the noise filter 2 and the termination circuit are attached to the high-frequency circuit. It can be seen that this arrangement can provide a greater noise reduction effect in the vicinity of about 550 MHz, which is the rejection frequency specified in the specification of the noise filter 2. Further, it is clear from FIG. 10B that the frequency-impedance characteristic specified in the specification of the noise filter 2 and the noise reduction characteristic due to the high-frequency circuit of the first preferred embodiment are similar.

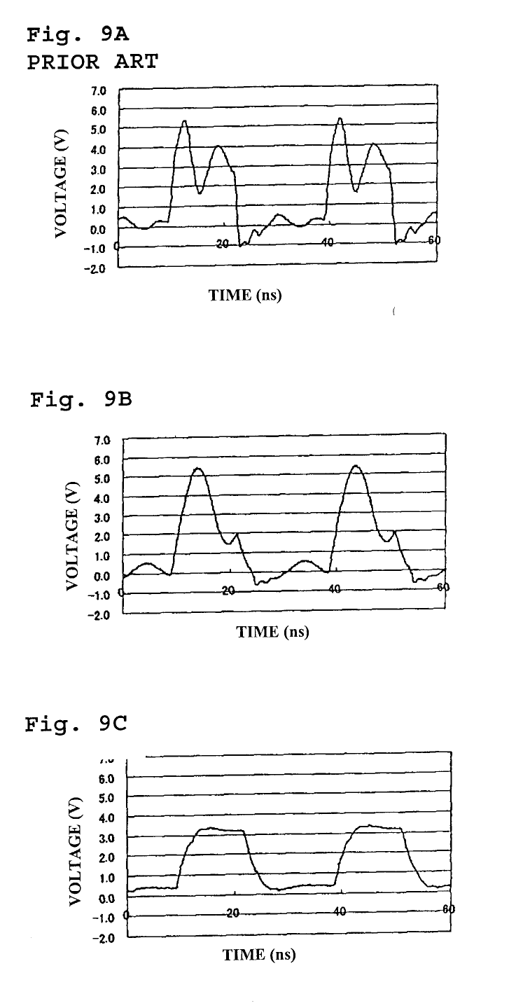

FIGS. 9A, 9B, and 9C each show a transmission waveform provided by the transmission line 1 that is similar to the one of the first preferred embodiment. Specifically, FIG. 9A shows a case in which nothing is attached to the transmission line 1, FIG. 9B shows a case in which only the noise filter 2 is attached, and FIG. 9C shows a case according to the first preferred embodiment in which the noise filter 2 and the termination circuit are attached. As is apparent from the comparison of these cases, the first preferred embodiment provides a very favorable waveform shaping effect. This waveform shaping effect is mainly due to the effect of the termination circuit.

In this manner, in the first preferred embodiment, the termination circuit, which is an impedance matching circuit, achieves impedance matching with the transmission line 1, so that no current and/or voltage standing wave is generated in the transmission line 1. In general, the generation of a standing wave impairs the noise elimination effect of a noise filter in a corresponding frequency. Thus, through the use of the termination circuit, the first preferred embodiment offers a characteristic in which no standing wave is generated, thereby making it possible to realize the noise elimination effect in the stop band specified in the specification of the noise filter 2, regardless of the characteristics of the transmission line 1. Additionally, the first preferred embodiment allows electric current to be drawn from the power supply 4 in accordance with the High/Low level of digital signals since the termination circuit is connected to the power supply 4, which is a constant voltage source, and allows distortion of the transmission waveform to be suppressed using the termination circuit.

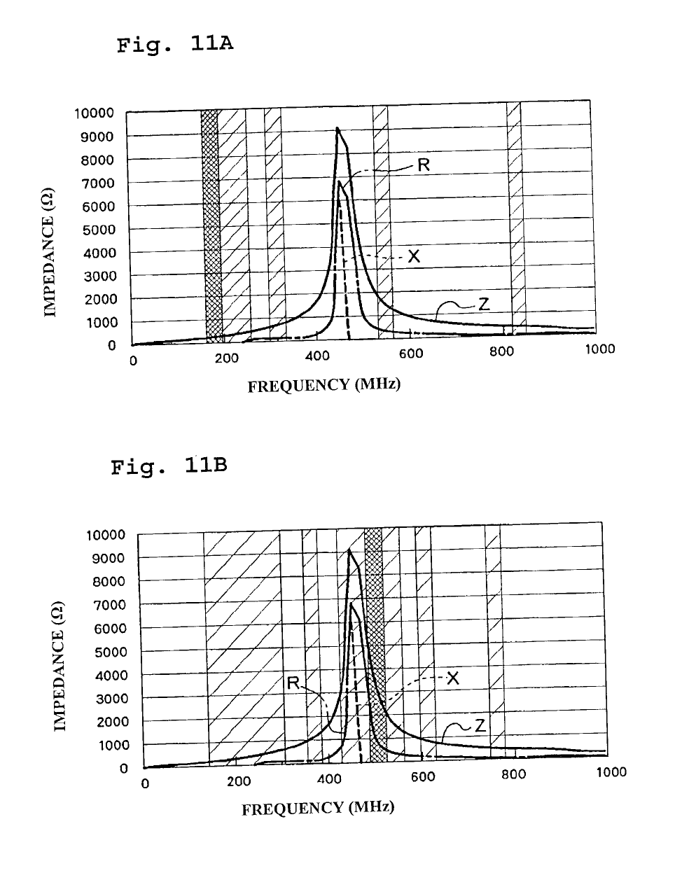

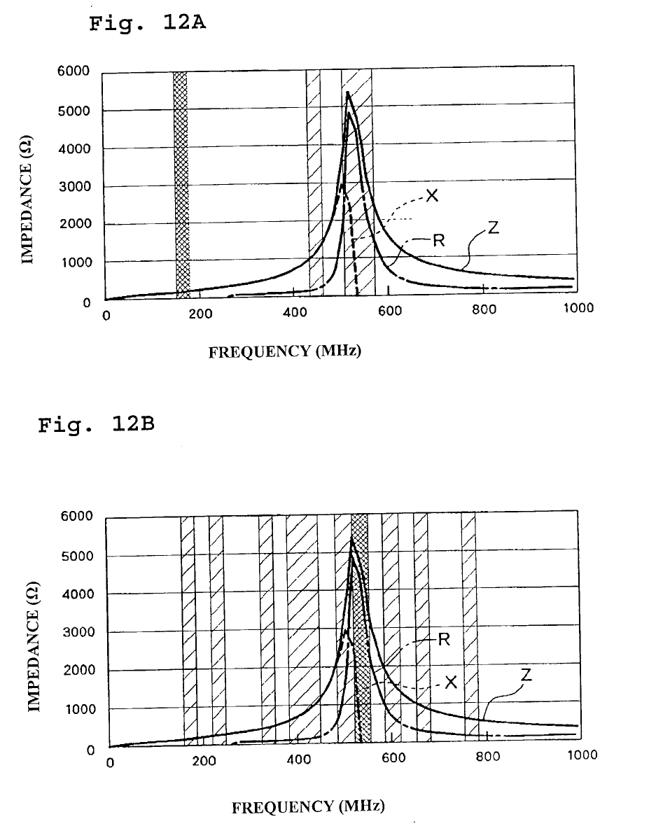

As a result of an experiment with varied characteristics of the noise filter 2 of the first preferred embodiment, as shown in FIGS. 11A and 11B (a first variation) and FIGS. 12A and 12B (a second variation), it can be proven that these variations can also provide the same advantages as the first preferred embodiment. FIGS. 11A and 12A show a case in which only the noise filter is attached, and FIGS. 11B and 12B show a case in which the noise filter and the termination circuit are attached.

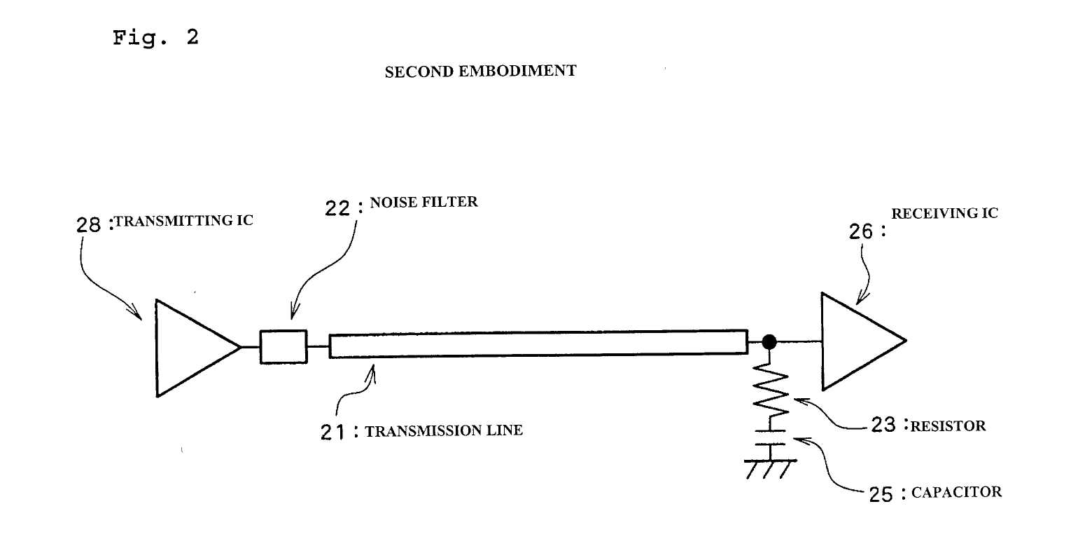

A second preferred embodiment will now be described. Referring to FIG. 2, a high-frequency circuit according to a second preferred embodiment uses so-called “series-RC parallel termination” to provide the termination circuit, and is configured such that a resistor 23 and a capacitor 25, which are connected in series with each other, constitute the termination circuit. This termination circuit provides a connection between the input of a receiving IC 26 and ground.

The impedance of the resistor 23 is preferably substantially equal to the characteristic impedance of a transmission line 21, thereby accomplishing impedance matching with the transmission line 21. The capacitance of a capacitor 25 preferably has a value that can sufficiently suppress waveform distortion, for example, a value that the RC time constant of the termination circuit becomes more than about five times a value corresponding to the rise time of the transmission waveform.

As a result, with a simple configuration, the second preferred embodiment can provide the same advantages as the first preferred embodiment. Additionally, since the capacitor 25 blocks low-frequency signals while allowing high-frequency signals to pass, a DC load due to the resistor 23 has no effect on a transmitting IC 28. Thus, the second preferred embodiment has an advantage of being able to reduce the power consumption over the first preferred embodiment.

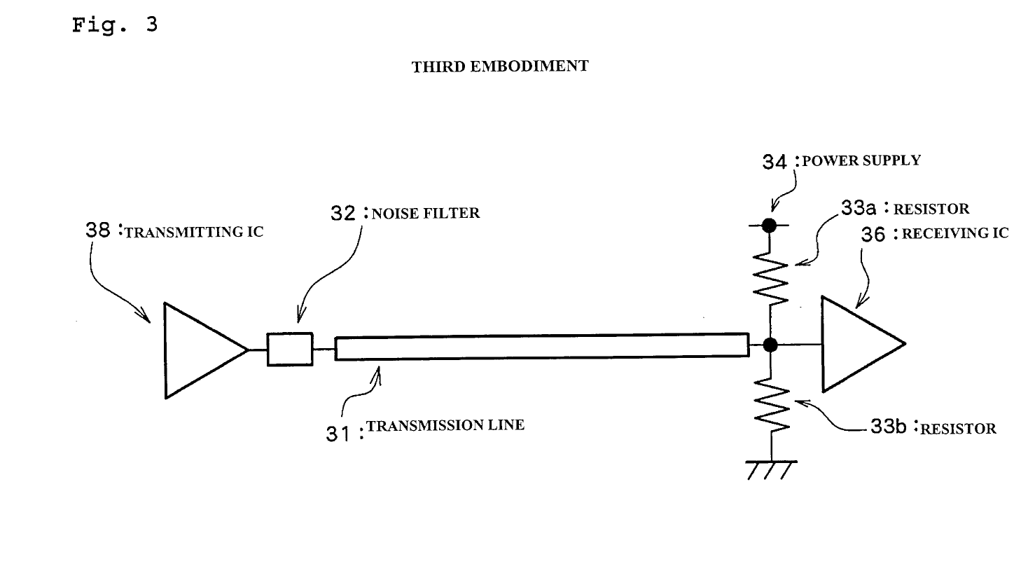

A third preferred embodiment will now be described. Referring to FIG. 3, a high-frequency circuit according to a third preferred embodiment uses so-called “Thevenin parallel termination” to provide the termination circuit, and is configured such that resistors 33a and 33b and a power supply 34 constitute the termination circuit. One end of the resistor 33a is connected to the power supply 34, which is a constant voltage supply, and one end of the other resistor 33b is connected to ground.

The total impedance of the resistors 33a and 33b is preferably substantially equal to the characteristic impedance of a transmission line 31 (based on Thevenin's theorem), thereby achieving impedance matching with the transmission line 31.

In the third preferred embodiment, while the electric current supplied from the power supply 34 is increased since the resistors 33a and 33b provide coupling between the power supply 34 and the ground, the third preferred embodiment can provide the same advantages as the first preferred embodiment, with a simple configuration. Additionally, the third preferred embodiment provides advantages in that the combination of resistances of the resistors 33a and 33b allows arbitrary setting of an electric current supplied to the receiving IC 36 and allows a reduction in the current drawn from the transmitting IC 38.

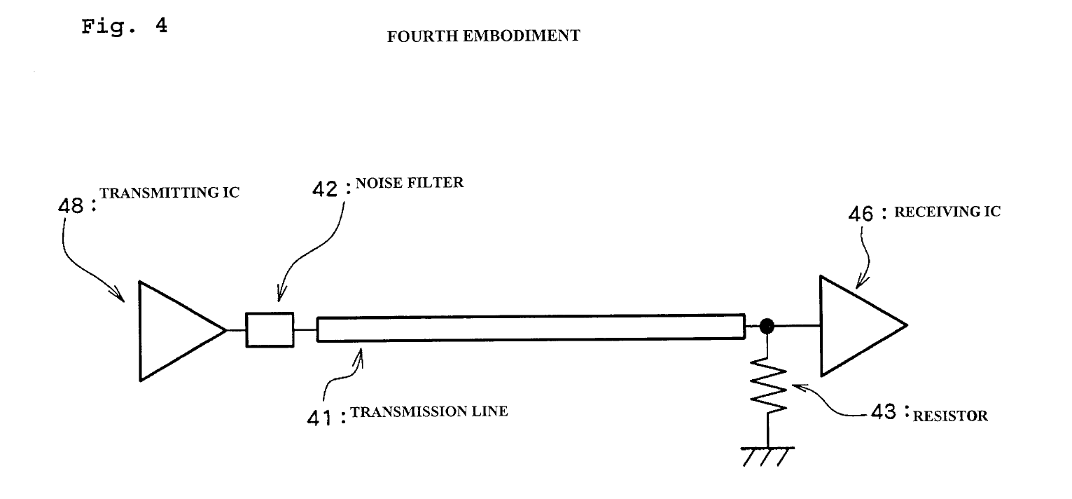

A fourth preferred embodiment will now be described. Referring to FIG. 4, a high-frequency circuit according to a fourth preferred embodiment uses simple “grounded parallel termination” to provide the termination circuit, and is configured such that a resistor 43 constitutes the termination circuit. One end of the resistor 43 is connected to ground.

The impedance of the resistor 43 is preferably substantially equal to the characteristic impedance of a transmission line 41, thereby achieving impedance matching with the transmission line 41.

As a result, the fourth preferred embodiment can provide the same advantages as the first preferred embodiment, with a very simple configuration.

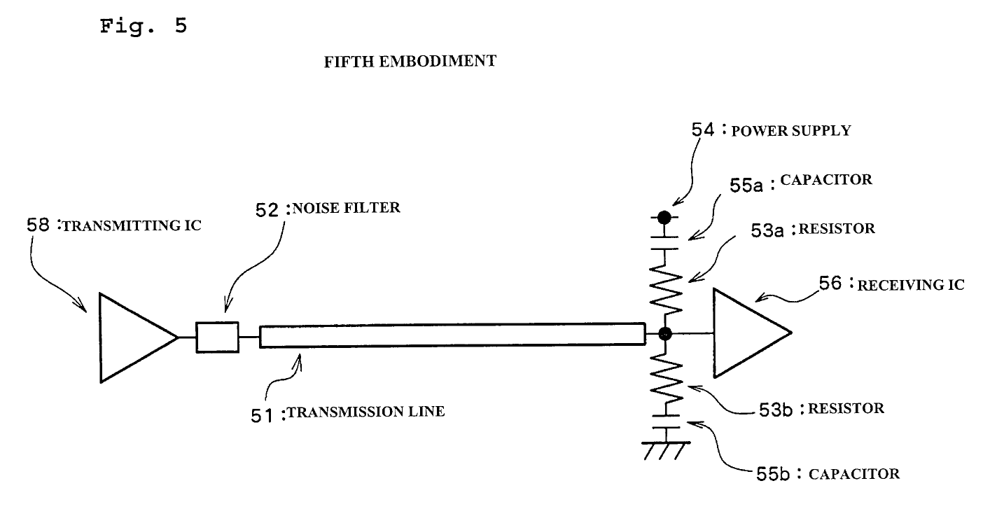

A fifth preferred embodiment will now be described. Referring to FIG. 5, a high-frequency circuit according to a fifth preferred embodiment uses “series-RC parallel termination” to provide the termination circuit. The high-frequency circuit is configured such that the resistors 53a and 53b, capacitors 55a and 55b, and a power supply 54, which is a constant voltage supply, constitute the termination circuit.

The total impedance of the resistors 53a and 53b is preferably substantially equal to the characteristic impedance of a transmission line 51 (based on Thevenin's theorem), thereby achieving impedance matching with the transmission line 51.

The total capacitance of the capacitors 55a and 55b is preferably set to a value that can sufficiently suppress waveform distortion, for example, to a such a value that the RC time constant of the resistor 53a and the capacitor 55a and the RC time constant of the resistor 53b and the capacitor 55b both become more than about five times a value corresponding to the rise time of the transmission waveform.

As a result, the fifth preferred embodiment can provide the same advantages as the first, second, and third preferred embodiments, with a simple configuration.

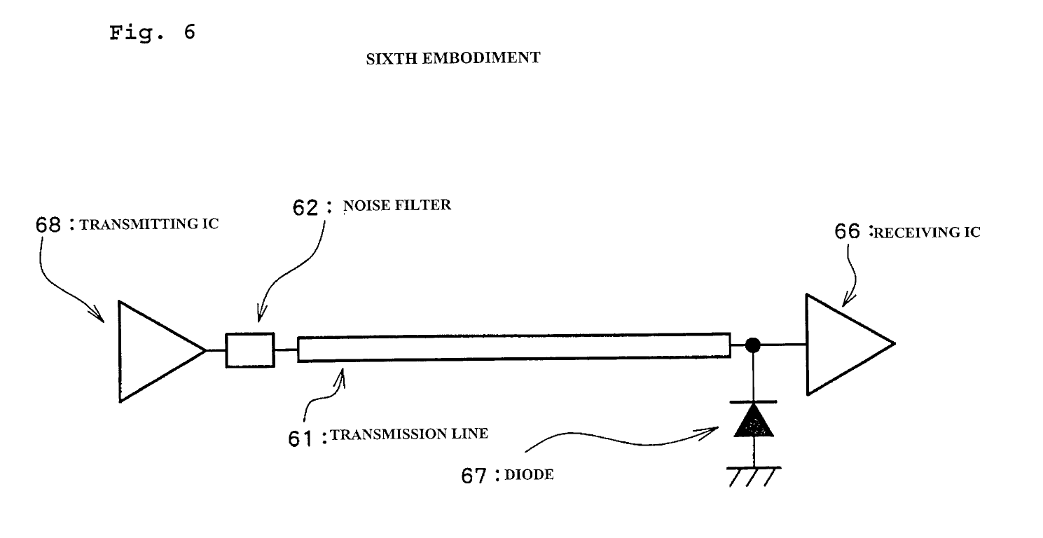

A sixth preferred embodiment will now be described. Referring to FIG. 6, a high-frequency circuit according to a sixth preferred embodiment uses “grounded diode parallel termination” to provide the termination circuit, and is configured such that a diode 67 constitutes the termination circuit. One end of the diode 67 is connected to ground.

As a result, the sixth preferred embodiment can provide the same advantages as the first preferred embodiment, with a very simple configuration, and has an advantage of providing much lower power consumption than the fourth preferred embodiment.

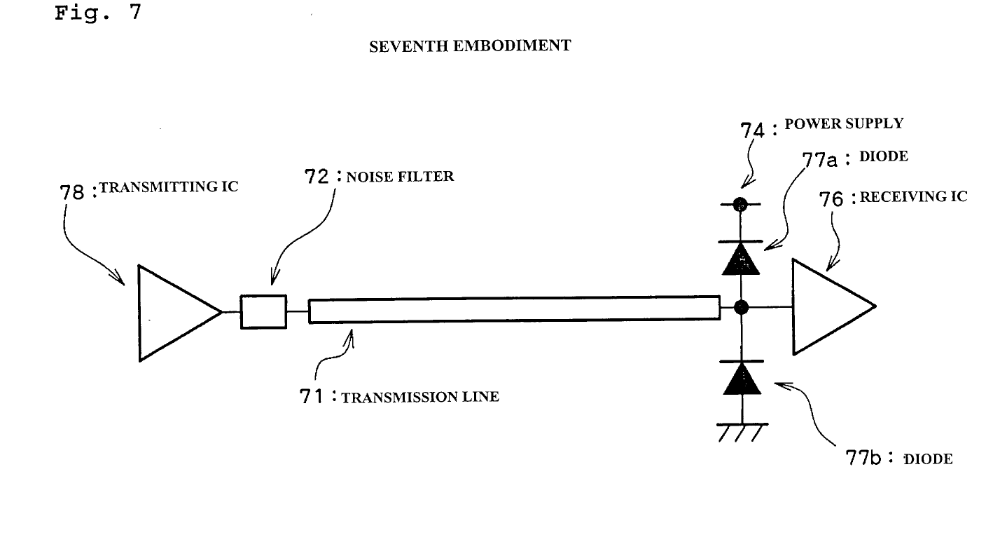

A seventh preferred embodiment will now be described. Referring to FIG. 7, a high-frequency circuit according to a seventh preferred embodiment uses “diode parallel termination” to provide the termination circuit, and is configured such that diodes 77a and 77b and a power supply 74, which is a constant voltage supply, constitute the termination circuit.

As a result, the seventh preferred embodiment can provide the same advantages as the first, third, and sixth preferred embodiments, with a very simple configuration.

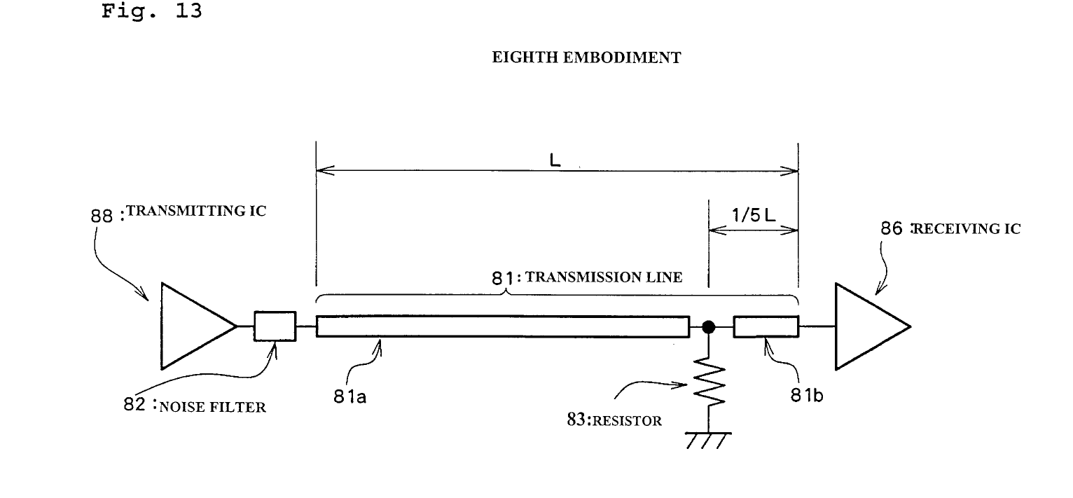

An eighth preferred embodiment will now be described. Referring to FIG. 13, in a high-frequency circuit according to an eighth preferred embodiment, the termination circuit is provided in a transmission line 81 at a location adjacent to the receiving end. In the example of FIG. 13, the termination circuit is provided between transmission lines 81a and 81b that constitute the transmission line 81. More specifically, the termination circuit is positioned in the transmission line 81 at about ⅕L (L is the total transmission line length) from a receiving IC 86 end toward the transmitting end.

In this manner, the case in which the termination circuit is spaced away from the receiving end of the transmission line 81 toward the transmitting end can also suppress a standing wave generated in the transmission line 81a between a transmitting IC 88 and the termination circuit. Thus, this arrangement can further reduce radiation noise.

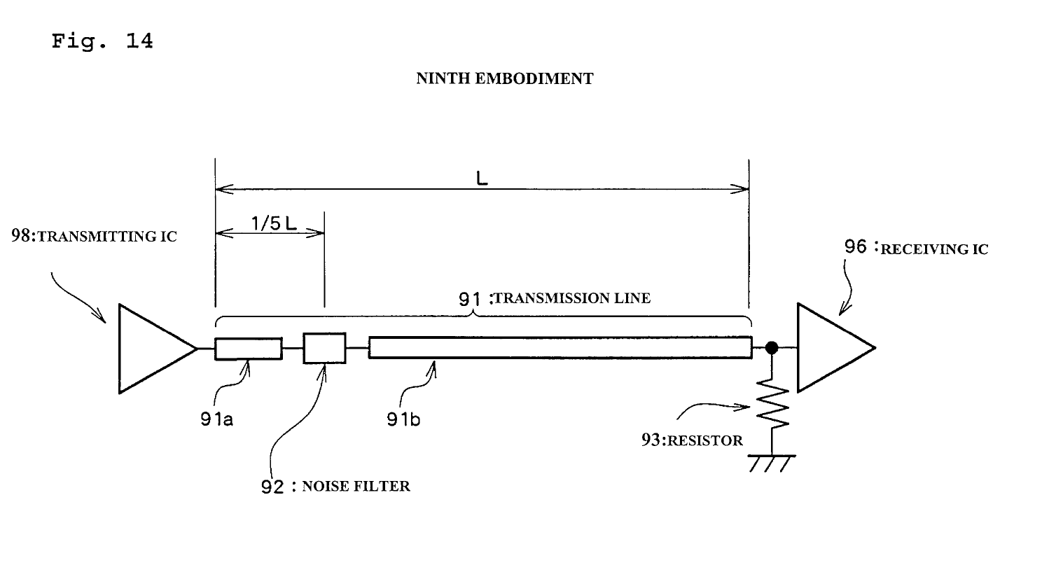

A ninth preferred embodiment will now be described. Referring to FIG. 14, in a high-frequency circuit according to a ninth preferred embodiment, a noise filter 92 is provided in a transmission line 91 at a location adjacent to an edge of the transmitting end. In the example of FIG. 14, the noise filter 92 is provided between transmission lines 91a and 91b that constitute the transmission line 91. More specifically, the noise filter 92 is positioned in the transmission line 91 at about ⅕L (L is the total transmission line length) from a transmitting IC 98 end toward the receiving end.

In this manner, even a case in which the noise filter 92 is spaced away from the transmitting end toward the receiving end can suppress a standing wave generated in the transmission line 91 between the transmitting IC 98 and the termination circuit. This arrangement can further reduce radiation noise compared to a case in which only the noise filter 92 is attached.

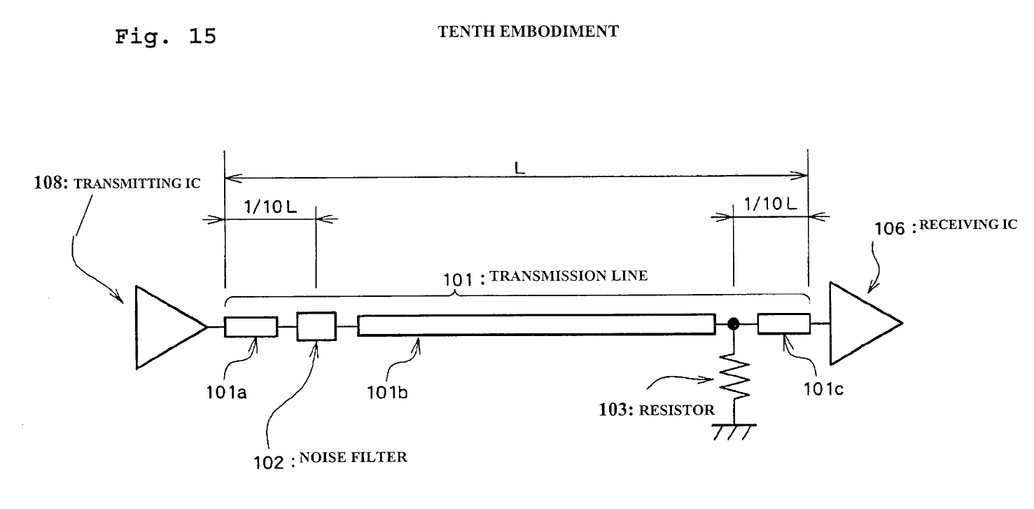

A tenth preferred embodiment will now be described. Referring to FIG. 15, in a high-frequency circuit according to a tenth preferred embodiment, a termination circuit is provided in a transmission line 101 at a location adjacent to the receiving end, and a noise filter 102 is provided in the transmission line 101 at a location adjacent to the transmitting end. In the example of FIG. 15, the termination circuit is provided between transmission lines 101b and 101c and the noise filter 102 is provided between transmission lines 101a and 101b. More specifically, the termination circuit is positioned in the transmission line 101 at about 1/10L (L is the total transmission line length) from a receiving IC 106 end toward the transmitting end. The noise filter 102 is positioned in the transmission line 101 at about 1/10L (L is the total transmission line length) from a transmitting IC 108 end toward the receiving end.

In this manner, even when the noise filter 102 and the termination circuit are both provided in the middle of the transmission line 101, it is possible to suppress a standing wave generated in transmission lines 101a and 101b between the transmitting IC 101 and the termination circuit, and it is possible to further reduce radiation noise compared to a case in which only the noise filter 102 is provided.

While a band elimination filter is preferably used as the noise filter in each preferred embodiment described above, the noise filter in the present invention may alternatively be a low-pass filter, a high-pass filter, or a band-pass filter.

In addition, the termination circuit in the present invention is not limited to the one in each preferred embodiment described above, and thus may be replaced with any circuit configuration that can achieve impedance matching with the transmission line to suppress a reflection wave. It is to be noted that any configuration with such a replacement also falls within the scope of the present invention.

While preferred embodiments of the invention have been described above, it is to be understood that variations and modifications will be apparent to those skilled in the art without departing the scope and spirit of the invention. The scope of the invention, therefore, is to be determined solely by the following claims.

What is claimed is:

1. A noise-reduction high-frequency circuit, comprising:
a transmission line;
a noise filter provided at a stage prior to the transmission line; and
an impedance matching circuit, provided at a stage subsequent to the transmission line, for matching the characteristic impedance of the transmission line.

2. A noise-reduction high-frequency circuit according to claim 1, wherein the impedance matching circuit is connected to one of ground and a constant voltage supply.

3. A noise-reduction high-frequency circuit according to claim 1, wherein the impedance matching circuit includes a resistance element and a capacitor which are connected in series, the resistance element having an impedance that is substantially equal to the characteristic impedance of the transmission line and the capacitor having a capacitance that is sufficient to suppresses waveform distortion.

4. A noise-reduction high-frequency circuit according to claim 1, wherein the impedance matching circuit includes a semiconductor element.

5. A noise-reduction high-frequency circuit according to claim 4, wherein the semiconductor element is a diode.

6. A noise-reduction high-frequency circuit, comprising:
a transmission line having a transmitting end and a receiving end;
a noise filter provided adjacent to the transmitting end of the transmission line and spaced away from the transmitting end toward the receiving end of the transmission line; and
an impedance matching circuit, provided at a stage subsequent to the transmission line, for matching the characteristic impedance of the transmission line.

7. A noise-reduction high-frequency circuit, comprising:
a transmission line having a transmitting end and a receiving end;
a noise filter provided at a stage prior to the transmission line; and
an impedance matching circuit for matching the characteristic impedance of the transmission line, the impedance matching circuit being provided adjacent to the receiving end of the transmission line and being spaced away from the receiving end toward the transmitting end of the transmission line.

8. A noise-reduction high-frequency circuit, comprising:
a transmission line having a receiving end and a transmitting end;
a noise filter provided adjacent to the transmitting end of the transmission line and spaced away from the transmitting end toward the receiving end of the transmission line; and
an impedance matching circuit for matching the characteristic impedance of the transmission line, the impedance matching circuit being located adjacent to the receiving end of the transmission line and being spaced away from the receiving end toward the transmitting end of the transmission line.

9. A noise-reduction high-frequency circuit according to claim 2, wherein the impedance matching circuit includes a resistance element and a capacitor which are connected in series, the resistance element having an impedance that is substantially equal to the characteristic impedance of the transmission line and the capacitor having a capacitance that is sufficient to suppress waveform distortion.

10. A noise-reduction high-frequency circuit according to claim 2, wherein the impedance matching circuit includes a semiconductor element.

11. A noise-reduction high-frequency circuit according to claim 3, wherein the impedance matching circuit includes a semiconductor element.

12. A noise-reduction high-frequency circuit according to claim 9, wherein the impedance matching circuit includes a semiconductor element.

13. A noise-reduction high-frequency circuit according to claim 10, wherein the semiconductor element is a diode.

14. A noise-reduction high-frequency circuit according to claim 11, wherein the semiconductor element is a diode.

15. A noise-reduction high-frequency circuit according to claim 12, wherein the semiconductor element is a diode.

16. A noise-reduction high-frequency circuit according to claim 1, further comprising a termination circuit that uses one of a grounded diode parallel termination, an active parallel termination, a Thevenin parallel termination, a grounded diode parallel termination, a diode parallel termination and a series-RC parallel termination.

17. A noise-reduction high-frequency circuit according to claim 6, further comprising a termination circuit that uses one of a grounded diode parallel termination, an active parallel termination, a Thevenin parallel termination, a grounded diode parallel termination, a diode parallel termination and a series-RC parallel termination.

18. A noise-reduction high-frequency circuit according to claim 7, further comprising a termination circuit that uses one of a grounded diode parallel termination, an active parallel termination, a Thevenin parallel termination, a grounded diode parallel termination, a diode parallel termination and a series-RC parallel termination.

19. A noise-reduction high-frequency circuit according to claim 8, further comprising a termination circuit that uses one of a grounded diode parallel termination, an active parallel termination, a Thevenin parallel termination, a grounded diode parallel termination, a diode parallel termination and a series-RC parallel termination.
